(19) United States
(12) Patent Application Publication
(10) Pub. No.: US 2026/0305037 A1
(43) Pub. Date: Oct. 1, 2026

(54) MICRO LED DISPLAY SUBSTRATE, MANUFACTURING METHOD THEREFOR, AND DISPLAY APPARATUS

(71) Applicants: BOE Technology Group Co., Ltd., Beijing (CN); Beijing BOE Technology Development Co., Ltd., Beijing (CN)

(72) Inventors: Chunping LONG, Beijing (CN); Jian XU, Beijing (CN); Mingxing WANG, Beijing (CN)

(21) Appl. No.: 19/477,651

(22) PCT Filed: Sep. 19, 2023
(86) PCT No.: PCT/CN2023/119580

§ 371 Date: Oct. 22, 2025

(51) Int. Cl. H10H 29/851; H10H 29/01

(52) U.S. Cl. CPC H10H 29/8514; H10H 29/0361

(57) ABSTRACT

Provided in the present disclosure are a Micro LED display substrate, a manufacturing method therefor, and a display apparatus. The Micro LED display substrate includes a drive backplane, a plurality of Micro LED structures, and a plurality of color conversion structures. The plurality of Micro LED structures is disposed at intervals on the drive backplane and is electrically connected to the drive backplane. The Micro LED structures are used for emitting light of a same color; one color conversion structure corresponds to one Micro LED structure, and each color conversion structure is located on the side facing away from the drive backplane of the corresponding Micro LED structure, and is used for converting the light emitted by the corresponding Micro LED structure into light of a set color.

### TECHNICAL FIELD

The disclosure herein relates the field of display technology, and particularly relates to a micro LED display substrate, a method for manufacturing the micro LED display substrate, and a display apparatus.

### BACKGROUND

Augmented Reality (AR) display devices and Virtual Reality (VR) display devices may use a Micro Light Emitting Diode (Micro LED) as a light-emitting component for display, so as to improve display brightness and image resolution. At present, AR/VR display devices usually adopt monochromatic Micro LEDs to display monochromatic images, resulting in relatively poor display effects. Therefore, how to realize full-color image display has become a current research focus.

### SUMMARY

The disclosure provides a micro LED display substrate, a method for manufacturing the micro LED display substrate, and a display apparatus for realizing color display.

In a first aspect, the disclosure provides a Micro LED display substrate, including: a driving backplane; a plurality of Micro LED structures, arranged on the driving backplane at intervals and electrically connected to the driving backplane, the plurality of Micro LED structures being configured to emit light of a same color; and a plurality of color conversion structures. One color conversion structure corresponds to one Micro LED structure, each of the plurality of color conversion structures is located at a side of a corresponding one of the plurality of Micro LED structures facing away from the driving backplane, and is configured to convert light emitted by the corresponding one of the plurality of Micro LED structures into light of a set color.

The Micro LED display substrate provided by the disclosure further including: a plurality of microlenses arranged at intervals. One microlens corresponds to one Micro LED structure, and each of the plurality of microlenses is located at a side of a corresponding one of the plurality of Micro LED structures facing away from the driving backplane.

In the Micro LED display substrate provided by the disclosure, the plurality of color conversion structures are located between the plurality of microlenses and the plurality of Micro LED structures; an orthographic projection of the plurality of color conversion structures on the driving backplane is located within an orthographic projection of the plurality of microlenses on the driving backplane. The Micro LED display substrate further includes a first insulating layer, located between the plurality of Micro LED structures and the plurality of color conversion structures, and covering the plurality of Micro LED structures. The Micro LED structure includes: a bottom surface and a top surface arranged opposite to each other; and a side surface, located between the bottom surface and the top surface and connected to the bottom surface and the top surface respectively. The first insulating layer includes a first portion covering the top surface of the Micro LED structure, and a second portion connected to the first portion and covering the side surface of the Micro LED structure.

In the Micro LED display substrate provided by the disclosure, the orthographic projection of the color conversion structure on the driving backplane is located within an orthographic projection of the first portion of the first insulating layer on the driving backplane. The Micro LED display substrate further includes a light blocking layer located at a side of the first insulating layer facing away from the driving backplane and being filled in a gap between two adjacent Micro LED structures and a gap between two adjacent color conversion structures. A surface of a side of the light blocking layer facing away from the driving backplane is connected to a surface of a side of an adjacent color conversion structure facing away from the driving backplane to form a continuous surface; and the microlens is located at a side of the color conversion structure and the light blocking layer facing away from the driving backplane and partially overlap with the light blocking layer.

In the Micro LED display substrate provided by the disclosure, the color conversion structure completely covers the first portion of the first insulating layer and at least partially covers the second portion of the first insulating layer; the microlens covers a surface of the color conversion structure and covers at least a portion of a surface of the first insulating layer not covered by the color conversion structure, to wrap the color conversion structure within the microlens. The Micro LED display substrate further includes a light blocking layer, filled in a gap between two adjacent microlenses. In a direction perpendicular to the driving backplane, a height of the light blocking layer is greater than or equal to a height of the color conversion structure.

In the Micro LED display substrate provided by the disclosure, the plurality of color conversion structures are located at a side of the plurality of microlenses facing away from the plurality of Micro LED structures. The Micro LED structure includes: a bottom surface and a top surface arranged opposite to each other; and a side surface, located between the bottom surface and the top surface and connected to the bottom surface and the top surface respectively. The microlens covers the top surface and at least a portion of the side surface of the Micro LED structure, to at least partially wrap the Micro LED structure within the microlens.

In the Micro LED display substrate provided by the disclosure, surfaces of the plurality of microlenses facing away from the driving backplane are flat surfaces or curved surfaces.

The Micro LED display substrate provided by the disclosure further includes: a second insulating layer, located at a side of the plurality of microlenses facing away from the driving backplane. The second insulating layer is in direct contact with the plurality of microlenses and covers the plurality of microlenses and gaps between the plurality of microlenses, to form a flat surface at the side of the plurality of microlenses facing away from the driving backplane.

In the Micro LED display substrate provided by the disclosure, the Micro LED structure includes: a first electrode, located at a side facing the driving backplane and electrically connected to the driving backplane; a first doped layer, located at a side of the first electrode facing away from the driving backplane; a multi-quantum well layer, located at a side of the first doped layer facing away from the first electrode; a second doped layer, located at a side of the multi-quantum well layer facing away from the first doped layer; a third insulating layer, located at a side of the second doped layer facing away from the driving backplane, the third insulating layer including an opening exposing the second doped layer, and the third insulating layer covering surfaces of the multi-quantum well layer, the first doped layer and the first electrode, to wrap the multi-quantum well layer, the first doped layer and the first electrode within the third insulating layer; and a second electrode, located at a side of the third insulating layer facing away from the driving backplane, and the second electrode covering a surface of the third insulating layer and is electrically connected to the second doped layer through the opening; and the second electrode being further electrically connected to the driving backplane. The Micro LED display backplane further includes: a conductive filling layer, located in a gap between two adjacent Micro LED structures. The conductive filling layer is directly formed at a surface of the second electrode and is electrically connected to the second electrode.

In the Micro LED display substrate provided by the disclosure, in a direction perpendicular to the driving backplane, a height of the conductive filling layer is less than a height of the Micro LED structure.

In the Micro LED display substrate provided by the disclosure, the color conversion structure includes a color conversion layer; and the color conversion layer is configured to convert at least part of the light emitted by the corresponding one of the Micro LED structures into the light of the set color.

In the Micro LED display substrate provided by the disclosure, the color conversion structure further includes a filter layer, located at a side of the color conversion layer facing away from the Micro LED structure. The filter layer is configured to filter out light with a color different from a color of light emitted by the color conversion layer after color conversion.

A second aspect of the disclosure provides a display apparatus includes the Micro LED display substrate according to any one of the above embodiments.

A third aspect of the disclosure provides a method for manufacturing a Micro LED display substrate, including: forming a plurality of Micro LED structures on a driving backplane; and forming a plurality of color conversion structures at a side of the plurality of Micro LED structures facing away from the driving backplane. One color conversion structure corresponds to one Micro LED structure, and each of the plurality of color conversion structures is located at a side of a corresponding one of the plurality of Micro LED structures facing away from the driving backplane.

The method provided by the disclosure further includes: forming a plurality of microlenses arranged at intervals at a side of the plurality of color conversion structures facing away from the driving backplane. One microlens corresponds to one Micro LED structure, and each of the plurality of microlenses is located at a side of a corresponding one of the Micro LED structures facing away from the driving backplane. Before the forming the plurality of color conversion structures at the side of the plurality of Micro LED structures facing away from the driving backplane, the method further includes: depositing a first insulating layer at the side of the plurality of Micro LED structures facing away from the driving backplane. The Micro LED structure includes a bottom surface and a top surface arranged opposite to each other, and a side surface located between the bottom surface and the top surface and connected to the bottom surface and the top surface respectively; the first insulating layer includes a first portion covering the top surface of the Micro LED structure, and a second portion connected to the first portion and covering the side surface of the Micro LED structure.

In the method provided by the disclosure further includes: the forming the plurality of color conversion structures at the side of the plurality of Micro LED structures facing away from the driving backplane includes: an orthographic projection of the color conversion structure on the driving backplane is located within an orthographic projection of the first portion of the first insulating layer on the driving backplane. Before the forming the plurality of microlenses arranged at intervals at the side of the plurality of color conversion structures facing away from the driving backplane, the method further includes: forming a light blocking layer at a side of the first insulating layer facing away from the driving backplane. The light blocking layer is filled in a gap between two adjacent Micro LED structures and a gap between two adjacent color conversion structures; a surface of a side of the light blocking layer facing away from the driving backplane is connected to a surface of a side of an adjacent color conversion structure facing away from the driving backplane, to form a continuous surface. The forming the plurality of microlenses arranged at intervals at the side of the plurality of color conversion structures facing away from the driving backplane includes: forming the plurality of microlenses at a side of the plurality of color conversion structures and the light blocking layer facing away from the driving backplane.

In the method provided by the disclosure, the forming the plurality of color conversion structures at the side of the plurality of Micro LED structure facing away from the driving backplane includes: the color conversion structure completely covers the first portion of the first insulating layer and at least partially covers the second portion of the first insulating layer. The forming the plurality of microlenses arranged at intervals at the side of the plurality of color conversion structures facing away from the driving backplane includes: the microlens covers a surface of the color conversion structure and covers at least a portion of a surface of the first insulating layer not covered by the color conversion structure, to wrap the color conversion structure within the microlens. The method further includes: forming a light blocking layer in a gap between two adjacent microlenses. In a direction perpendicular to the driving backplane, a height of the light blocking layer is greater than or equal to a height of the color conversion structure.

In the method provided by the disclosure, the Micro LED structure includes a bottom surface and a top surface arranged opposite to each other, and a side surface located between the bottom surface and the top surface and connected to the bottom surface and the top surface respectively. Before the forming the plurality of color conversion structures at the side of the plurality of Micro LED structures facing away from the driving backplane, the method further includes: forming a plurality of microlenses arranged at intervals at the side of the plurality of Micro LED structures facing away from the driving backplane. One microlens corresponds to one Micro LED structure, and each of the plurality of microlenses is located at a side of a corresponding one of the plurality of Micro LED structures facing away from the driving backplane; an orthographic projection of the color conversion structure on the driving backplane and an orthographic projection of the Micro LED structure on the driving backplane are both located within an orthographic projection of the microlens on the driving backplane; the microlens covers the top surface and at least a portion of the side surface of the Micro LED structure, to at least partially wrap the Micro LED structure within the microlens. The forming the plurality of color conversion structures at the side of the plurality of Micro LED structures facing away from the driving backplane includes: forming the plurality of color conversion structures at the side of the plurality of microlenses facing away from the driving backplane.

### BRIEF DESCRIPTION OF FIGURES

In order to illustrate technical solutions of embodiments of the disclosure more clearly, drawings needing to be used in descriptions of the embodiments will be introduced below briefly. Apparently, the drawings described below are only some embodiments of the disclosure, and those ordinarily skilled in the art can further obtain other drawings according to these drawings without inventive efforts.

FIG. 1 is a first schematic structural diagram of a cross-section of a Micro LED display substrate provided by an embodiment of the disclosure.

FIG. 2 is a second schematic structural diagram of a cross-section of a Micro LED display substrate provided by an embodiment of the disclosure.

FIG. 3 is a third schematic structural diagram of a cross-section of a Micro LED display substrate provided by an embodiment of the disclosure.

FIG. 4 is a fourth schematic structural diagram of a cross-section of a Micro LED display substrate provided by an embodiment of the disclosure.

FIG. 5 is a fifth schematic structural diagram of a cross-section of a Micro LED display substrate provided by an embodiment of the disclosure.

FIG. 6 is a sixth schematic structural diagram of a cross-section of a Micro LED display substrate provided by an embodiment of the disclosure.

FIG. 7 is a seventh schematic structural diagram of a cross-section of a Micro LED display substrate provided by an embodiment of the disclosure.

FIG. 8 is an eighth schematic structural diagram of a cross-section of a Micro LED display substrate provided by an embodiment of the disclosure.

FIG. 9 is a ninth schematic structural diagram of a cross-section of a Micro LED display substrate provided by an embodiment of the disclosure.

FIG. 10 is a schematic diagram of a manufacturing process of a microlens provided by an embodiment of the disclosure.

FIG. 11 is a flow chart of a manufacturing method of a Micro LED display substrate provided by an embodiment of the disclosure.

### DETAILED DESCRIPTION

In order to make the objectives, technical solutions and advantages of the embodiments of the disclosure clearer, the disclosure will be further described below with reference to the drawings and the embodiments. However, the example implementations can be implemented in various forms and should not be construed as being limited to the implementations set forth herein; on the contrary, these implementations are provided to make the disclosure more comprehensive and complete, and to fully convey the concept of the example implementations to those skilled in the art. The same reference signs in the drawings indicate the same or similar structures, and thus repeated descriptions thereof will be omitted. The words describing positions and directions in the disclosure are all explained by taking the drawings as examples, but changes can also be made as needed, and all such changes are included within the protection scope of the disclosure. The drawings of the disclosure are only used to illustrate the relative positional relationship and do not represent the actual scale.

Augmented Reality (AR) display devices and Virtual Reality (VR) display devices may use a Micro Light Emitting Diode (Micro LED) as a light-emitting component for display, to improve display brightness and image resolution. At present, AR/VR display devices usually adopt monochromatic Micro LEDs to display monochromatic images, resulting in relatively poor display effects. Therefore, how to realize full-color image display has become a current research focus.

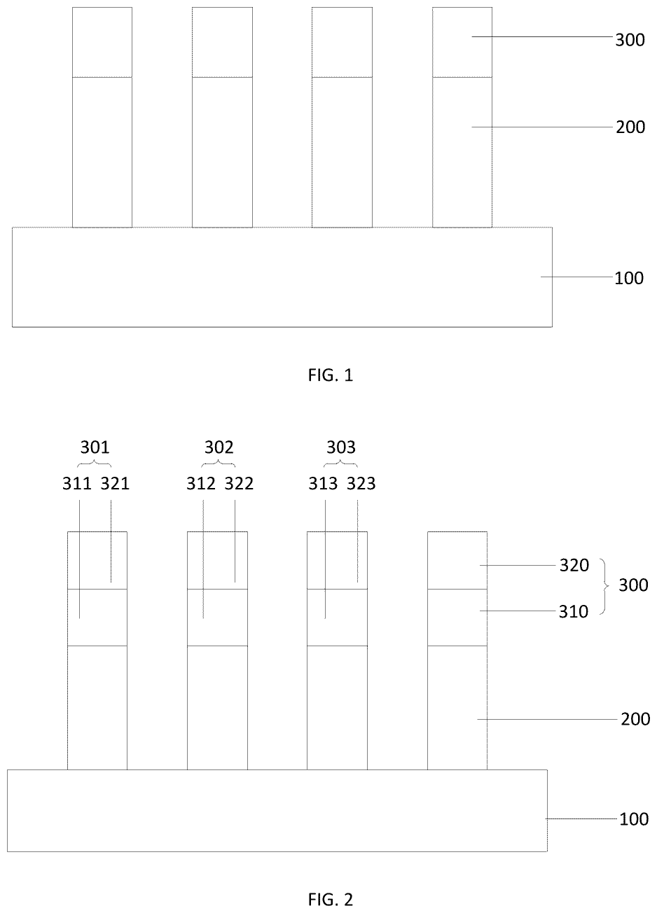

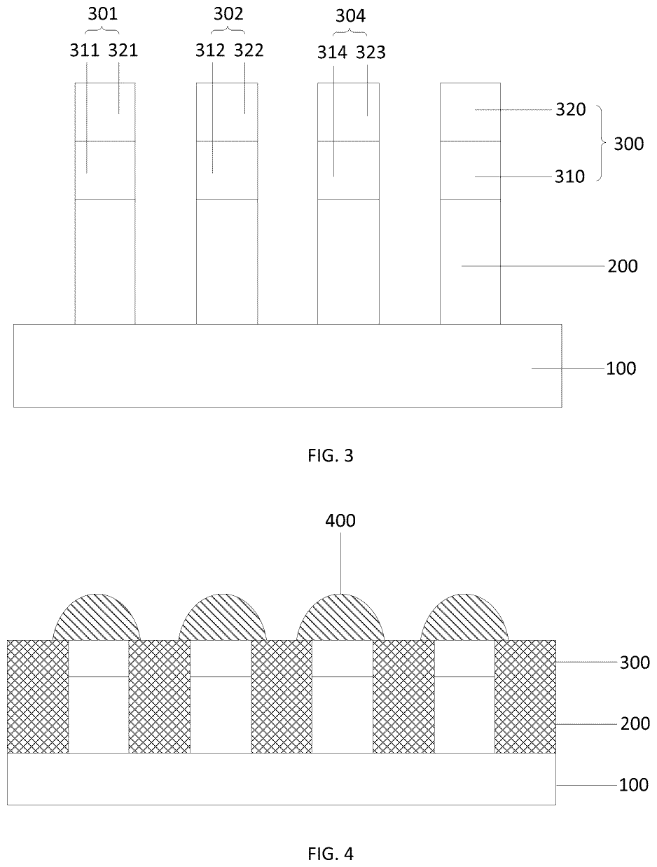

FIG. 1 is a first schematic structural diagram of a cross-section of a Micro LED display substrate provided by an embodiment of the disclosure; FIG. 2 is a second schematic structural diagram of a cross-section of a Micro LED display substrate provided by an embodiment of the disclosure; FIG. 3 is a third schematic structural diagram of a cross-section of a Micro LED display substrate provided by an embodiment of the disclosure.

In a first aspect of embodiments of the disclosure, a Micro LED display substrate is provided. As shown in FIG. 1, the Micro LED display substrate includes: a driving backplane 100, a plurality of Micro LED structures 200, and a plurality of color conversion structures 300. The plurality of Micro LED structures 200 are arranged on the driving backplane 100 at intervals and are electrically connected to the driving backplane 100. A driving circuit is arranged in the driving backplane 100 for driving the Micro LED structures 200 to emit light. In the embodiments of the disclosure, each Micro LED structure 200 can emit light of the same color under the drive of the driving backplane 100. The plurality of color conversion structures 300 are located at a side of the plurality of Micro LED structures 200 facing away from the driving backplane 100. Among them, one color conversion structure 300 corresponds to one Micro LED structure 200, and each of the plurality of color conversion structures 300 is located at a side of a corresponding one of the plurality of Micro LED structures 200 facing away from the driving backplane 100, and is configured to convert light emitted by the corresponding one of the plurality of Micro LED structures 200 into light of a set color.

In a specific implementation, an orthographic projection of each Micro LED structure 200 on the driving backplane 100 can be set to be located within an orthographic projection of the corresponding one of the plurality of color conversion structures 300 on the driving backplane 100, so that more light emitted by the Micro LED structure 200 can be incident into the color conversion structure 300, thereby improving light utilization.

For example, in some embodiments, as shown in FIG. 2, the Micro LED structures may emit ultraviolet (UV) light, and the plurality of color conversion structures 300 may include a red color conversion structure 301, a green color conversion structure 302, and a blue color conversion structure 303. The red color conversion structure 301 is configured to convert the incident UV light into red light, the green color conversion structure 302 is configured to convert the incident UV light into green light, and the blue color conversion structure 303 is configured to convert the incident UV light into blue light. The red light, green light, and blue light emitted after passing through the color conversion structures 300 are mixed in different proportions to display a color image.

In some embodiments, as shown in FIG. 3, the Micro LED structures 200 may emit blue light, and the plurality of color conversion structures 300 may include a red color conversion structure 301 and a green color conversion structure 302. The red color conversion structure 301 is configured to convert the incident blue light into red light, and the green color conversion structure 302 is configured to convert the incident blue light into green light. The Micro LED display substrate further includes a blue light transmission structure 304, one blue light transmission structure 304 corresponds to one Micro LED structure 200, and the blue light transmission structure 304 is located at a side of a corresponding one of the Micro LED structures 200 facing away from the driving backplane 100. The blue light transmission structure 304 is configured to transmit the incident blue light, and the red light and green light emitted after color conversion by the color conversion structure 300 are mixed with the blue light transmitted by the blue light transmission structure 304 in different proportions, thereby displaying a color image. In specific implementation, a material of the blue light transmission structure 304 may include scattering particles to improve the uniformity of light, or the blue light transmission structure 304 may be replaced by a blue filter layer to filter out incident stray light, thereby emitting purer blue light. In some embodiments, the blue light transmission structure 304 may not be provided, so that the blue light emitted by the Micro LED structure and the red light and green light emitted by the color conversion structure are directly used to display a color image, which is not limited here.

In a specific implementation, the Micro LED structures 200 may also be used to emit light of other colors and/or the color conversion structure 300 may also be used to convert the light emitted by the Micro LED structure 200 into light of more or fewer colors than red, green, and blue, as long as color image display can be achieved, which is not limited here.

In some embodiments, the color conversion structure 300 includes a color conversion layer. The color conversion layer is used to convert the light emitted by the Micro LED structure 200 into light of a set color.

For example, in some embodiments, as shown in FIG. 2, the Micro LED structures 200 may emit ultraviolet (UV) light, and the plurality of color conversion structures 300 may include a red color conversion structure 301, a green color conversion structure 302, and a blue color conversion structure 303. The red color conversion structure 301 includes a red color conversion layer 311 for converting incident UV light into red light; the green color conversion structure 302 includes a green color conversion layer 312 for converting incident UV light into green light; and the blue color conversion structure 303 includes a blue color conversion layer 313 for converting incident UV light into blue light.

In some embodiments, as shown in FIG. 3, the Micro LED structures may emit blue light, and the plurality of color conversion structures 300 may include a red color conversion structure 301 and a green color conversion structure 302. The red color conversion structure 301 includes a red conversion layer 311 for converting incident blue light into red light; the green color conversion structure 302 includes a green color conversion layer 312 for converting incident blue light into green light. The Micro LED display substrate further includes a blue light transmission structure 304, one blue light transmission structure 304 corresponds to one Micro LED structure, the blue light transmission structure 304 is located at the side of the corresponding one of the Micro LED structures away from the driving backplane, and the blue light transmission structure 304 includes a transparent layer 314 for transmitting the incident blue light. The transparent layer 314 may be made of a resin matrix, and scattering particles are doped in the resin matrix, which is not limited here. In specific implementation, the transparent layer may not be set, which is not limited here.

In the embodiments of the disclosure, the color conversion layer 310 may be made of fluorescent material or quantum dot (QD) material. The Quantum dot material has high luminescence performance and color conversion efficiency, which can improve the utilization rate of light, obtain monochromatic light with higher purity, and improve the color gamut. The color of the light emitted by the quantum dot material when excited is related to the size of the quantum dots, and the excitation light of a corresponding color can be obtained by controlling the size of the quantum dots. In specific implementation, the color conversion layer 310 may be made of a quantum dot resin with scattering particles to form color conversion layers spaced apart from each other through a photolithography process. The scattering particles can be light scattering materials such as titanium dioxide, which are not limited here. A thickness of the color conversion layer 310 may be set in the range of 1 μm to 5 μm, specifically may be set to 2 μm, which is not limited here.

In some embodiments, the color conversion structure 300 further includes a filter layer 320. The filter layer 320 is located at a side of the color conversion layer 310 facing away from the Micro LED structure 200. In a specific implementation, due to the conversion efficiency limitation of the color conversion layer 310, it cannot perform color conversion on all incident light. Therefore, the filter layer 320 is disposed on the light-emitting side of the color conversion layer 310 to filter out light with a color different from the color of the light emitted after color conversion by the color conversion layer 310, for example, filtering out the unconverted ultraviolet light or blue light emitted by the Micro LED structure 200, so that the color of the light emitted by the color conversion structure 300 is purer. The material of the filter layer 320 may be a filter material such as a color film, and a thickness of the filter layer may be set in the range of 0.5 μm to 2 μm, specifically can be set to 1 μm, which is not limited here.

For example, in some embodiments, as shown in FIG. 2, the Micro LED structures may emit ultraviolet (UV) light, and the plurality of color conversion structures 300 may include a red color conversion structure 301, a green color conversion structure 302, and a blue color conversion structure 303. The red color conversion structure 301 includes a red color conversion layer 311 and a red filter layer 321. The red color conversion layer 311 is configured to convert at least part of the incident UV light into red light. The red filter layer 321 is configured to filter out the incident UV light that is not converted by the red color conversion layer 311 and stray light other than the red light, so that the red color conversion structure 301 emits purer red light. The green color conversion structure 302 includes a green color conversion layer 312 and a green filter layer 322. The green color conversion layer 312 is configured to convert at least part of the incident UV light into green light. The green filter layer 322 is configured to filter out the incident UV light that is not converted by the green color conversion layer 312 and stray light other than the green light. The blue color conversion structure 303 includes a blue color conversion layer 313 and a blue filter layer 323. The blue color conversion layer 313 is configured to convert at least part of the incident UV light into blue light. The blue filter layer 323 is configured to filter out the incident UV light that is not converted by the blue color conversion layer 312 and stray light other than the blue light.

In some embodiments, as shown in FIG. 3, the Micro LED structures may emit blue light, and the plurality of color conversion structures 300 may include a red color conversion structure 301 and a green color conversion structure 302. The red color conversion structure 301 includes a red color conversion layer 311 and a red filter layer 321. The red color conversion layer 311 is configured to convert at least part of the incident blue light into red light, and the red filter layer 321 is configured to filter out the incident blue light that is not converted by the red color conversion layer 311 and stray light other than the red light, so that the red color conversion structure 301 emits purer red light. The green color conversion structure 302 includes a green color conversion layer 312 and a green filter layer 322. The green color conversion layer 312 is configured to convert at least part of the incident blue light into green light, and the green filter layer 322 is used to filter out the incident blue light that is not converted by the green color conversion layer 312 and stray light other than the green light. The Micro LED display substrate further includes a blue light transmission structure 304, one blue light transmission structure 304 corresponds to one Micro LED structure, and the blue light transmission structure 304 is located at a side of the corresponding one of the Micro LED structures facing away from the driving backplane. The blue light transmission structure 304 includes a transparent layer 314 and a blue filter layer 323, the transparent layer 314 is configured to transmit blue light, and the blue filter layer 323 is configured to filter out stray light other than blue light. In a specific implementation, the transparent layer 314 and/or the blue filter layer 323 may not be provided, which is not limited here.

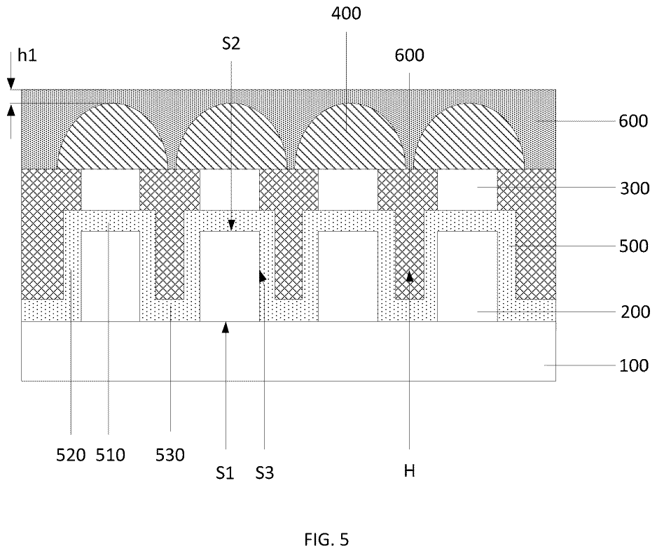

FIG. 4 is a fourth schematic structural diagram of a cross-section of a Micro LED display substrate provided by an embodiment of the disclosure.

In some embodiments, as shown in FIG. 4, the Micro LED display substrate further includes: a plurality of microlenses 400 arranged at intervals. One microlens 400 corresponds to one Micro LED structure 200, and each of the microlenses 400 is located at a side of a corresponding one of the Micro LED structures 200 facing away from the driving backplane 100. The microlenses 400 may adjust an exit angle of the light and improve the light output efficiency.

FIG. 5 is a fifth schematic structural diagram of a cross-section of a Micro LED display substrate provided by an embodiment of the disclosure.

In some embodiments, as shown in FIG. 5, the color conversion structures 300 are located between the microlenses 400 and the Micro LED structures 200. In a specific implementation, an orthographic projection of the color conversion structures 300 on the driving backplane 100 is located within an orthographic projection of the microlenses 400 on the driving backplane 100, so that more light emitted by the color conversion structures 300 can be incident to the microlens 400, thereby improving light utilization.

As shown in FIG. 5, the Micro LED display substrate further includes: a first insulating layer 500, which is located between the Micro LED structures 200 and the color conversion structures 300 and covers the Micro LED structures 200. The color conversion structures 300 are formed at a side of the first insulating layer 500 facing away from the Micro LED structures 200, and the first insulating layer 500 can insulate and protect the Micro LED structures 200. A material of the first insulating layer 500 may be selected from insulating materials such as SiO2, which is not limited here.

As shown in FIG. 5, the Micro LED structure 200 includes a bottom surface S1 and a top surface S2 that are arranged opposite to each other, and a side surface S3 that is located between the bottom surface S1 and the top surface S2 and connected to the bottom surface S1 and the top surface S2 respectively. The top surface S2 of the Micro LED structure 200 is located at a side of the bottom surface S1 facing away from the driving backplane 100, and the top surface S2 is usually used as a light-emitting surface of the Micro LED structure 200 for emitting light. The first insulating layer 500 includes a first portion 210 covering the top surface S2 of the Micro LED structure 200, and a second portion 520 connected to the first portion 210 and covering the side surface S3 of the Micro LED structure 200. In a specific implementation, the first insulating layer 500 may be formed as a full-face layer at the side of the Micro LED structure 200 facing away from the driving backplane 100 through processes such as chemical vapor deposition, and the first insulating layer 500 further includes a third portion 530 formed at a gap between two adjacent Micro LED structures 200. A thickness of the first insulating layer 500 is in the range of 100 nm to 500 nm, which is much smaller than a height of the Micro LED structure 200. After the first insulating layer 500 is deposited, the third portion 530 of the first insulating layer 500 cannot completely fill the gap between adjacent Micro LED structures 200, thereby forming a pit H. In a specific implementation, the thickness of the first insulating layer 500 can be set to 300 nm, which is not limited here.

In some embodiments, as shown in FIG. 5, the Micro LED display substrate further includes: a second insulating layer 600. The second insulating layer 600 is located at the side of the microlenses 400 facing away from the driving backplane 100. The second insulating layer 600 covers the surfaces of the microlenses 400 and fills gaps between the microlenses 400 to form a flat surface at the side of the microlenses 400 facing away from the driving substrate 100, thereby playing a role of planarization and protection. In a specific implementation, a material of the second insulating layer 600 may be an organic material, such as polyimide, acrylic, photoresist, etc., which is not limited here. A height of the second insulating layer 600 is greater than a height of the microlens 400. In a specific implementation, a distance h1 between a surface of a side of the second insulating layer 600 facing away from the driving backplane 100 and the highest point of the top of the microlens 400 ranges from 0.1 μm to 2 μm, and may be specifically set to 0.8 μm, which is not limited here.

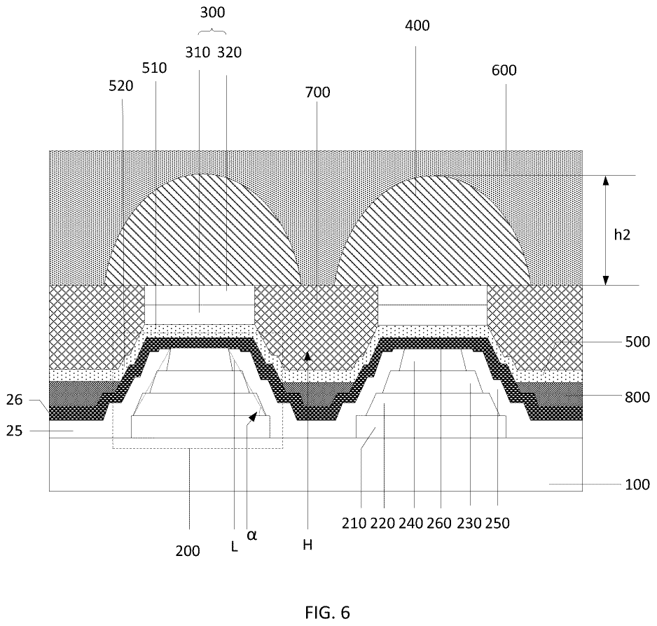

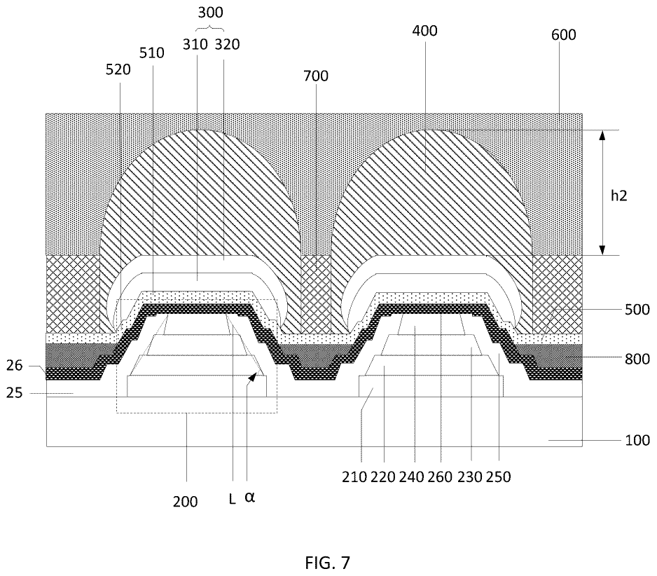

FIG. 6 is a sixth schematic structural diagram of a cross-section of a Micro LED display substrate provided by an embodiment of the disclosure; FIG. 7 is a seventh schematic structural diagram of a cross-section of a Micro LED display substrate provided by an embodiment of the disclosure.

In the embodiment shown in FIG. 5, the Micro LED structure 200 may be a horizontal structure or a vertical structure. The P electrode and the N electrode of the Micro LED structure 200 with a horizontal structure are located at the same side of the Micro LED structure 200, and the P electrode and the N electrode of the Micro LED structure 200 with a vertical structure are located at opposite sides of the Micro LED structure 200. FIG. 6 and FIG. 7 illustrate a specific structure of the Micro LED display substrate in the embodiment shown in FIG. 5 by taking a Micro LED structure 200 with a vertical structure as an example. As shown in FIG. 6 and FIG. 7, the Micro LED structure 200 includes a first electrode 210, a first doped layer 220, a multi-quantum well layer (MQW) 230, a second doped layer 240, a third insulating layer 250, and a second electrode 260 stacked in a direction away from the driving backplane 100.

The first electrode 210 is electrically connected to the driving backplane 100. In a specific implementation, the first electrode 210 may include a conductive layer directly in contact with the driving backplane 100 and a bonding layer located at a side of the conductive layer facing away from the driving backplane 100. The bonding layer can improve the connection performance between the Micro LED structure 200 and the driving backplane 100, and enhance properties such as mechanical, electrical, thermal performance.

The first doped layer 220 is electrically connected to the first electrode 210, and the second doped layer 240 is electrically connected to the second electrode 260. The first doped layer 220 may be a P-type semiconductor layer (or an N-type semiconductor layer), and the second doped layer 220 may be an N-type semiconductor layer (or a P-type semiconductor layer). In the embodiments, the first doped layer 220 is a P-type semiconductor layer, and its material may be GaN doped with Mg, and its thickness may be set in the range from 100 nm to 500 nm, and may be specifically set to 220 nm, which is not limited here. The second doped layer 240 is an N-type semiconductor layer, and its material may be GaN doped with Si, and its thickness may be set in the range from 10 nm to 100 nm, and may be specifically set to 30 nm, which is not limited here. The first electrode 210 is a P-electrode, and the first electrode 210 includes a conductive layer and a bonding layer which are stacked. The conductive layer may be a single-layer structure or a multi-layer structure in which a plurality of conductive film layers are stacked, and the bonding layer may be a single-layer structure or a multi-layer structure in which a plurality of conductive film layers are stacked, which is not limited here. A thickness of the first electrode 210 may be set in the range from 500 nm to 3000 nm. In a specific implementation, the conductive layer of the first electrode 210 may include multiple conductive film layers such as ITO, Cr, Pt, Ti, Au, SnPt, Au, SnPt, Au, etc. stacked in a direction away from the driving backplane 100, and thicknesses of the respective conductive film layers are set to 138 nm, 8.5 nm, 36.5 nm, 12.2 nm, 118.1 nm, 87.6 nm, 102.8 nm, 113.7 nm, 133.2 nm in sequence, and the bonding layer of the first electrode 210 may include multiple conductive film layers such as Ti, Pt, Ti, etc. stacked in the direction away from the driving backplane 100, and thicknesses of the respective conductive film layers is set to 7.0 nm, 5.7 nm, 20 nm in sequence. The second electrode 260 is an N electrode, and the second electrode 260 may be a single-layer structure or a multi-layer structure in which a plurality of conductive film layers are stacked, which is not limited here. In a specific implementation, the conductive layer of the first electrode 210 may include multiple film layers such as Cr and Pt stacked in the direction away from the driving backplane 100. A thickness of Cr may range from 10 nm to 50 nm, and specifically, it may be 30 nm. A thickness of Pt may range from 100 nm to 500 nm, and specifically, it may be 270 nm, which is not limited here.

The multi-quantum well layer 230 is located between the first doped layer 220 and the second doped layer 230. The electrons of the N-type semiconductor layer and the holes of the P-type semiconductor layer are recombined in the quantum well layer 230 to generate photons, thereby emitting light. In a specific implementation, the multi-quantum well layer 230 may be a periodic structure in which InGaN layers and GaN layers are alternately grown. The total thickness of the multi-quantum well layer 230 is between 50 nm and 500 nm, and can be specifically set to 130 nm, which is not limited here.

The third insulating layer 250 is located at a side of the second doped layer 240 facing away from the driving backplane 100. The third insulating layer 250 includes an opening exposing the second doped layer 240, so as to facilitate the connection between the second electrode 260 and the second doped layer 240. The third insulating layer 250 covers the surfaces of the multi-quantum well layer 230, the first doped layer 220 and the first electrode 210, so as to wrap the multi-quantum well layer 230, the first doped layer 220 and the first electrode 210 within the third insulating layer 250, and to play a role of insulation and protection, thereby avoiding unnecessary electrical contact with the second electrode 260. The third insulating layer 250 covering the surfaces of the multi-quantum well layer 230, the first doped layer 220 and the first electrode 210 specifically refers to the third insulating layer 250 covering the surfaces of the multi-quantum well layer 230, the first doped layer 220 and the first electrode 210 that are not covered by other film layers, such as covering side surfaces of the multi-quantum well layer 230, the first doped layer 220 and the first electrode 210 in FIG. 5, so as to play a role of protection. The second electrode 260 is located at a side of the third insulating layer 250 facing away from the driving backplane 100. The second electrode 260 covers a surface of the third insulating layer 250 and is electrically connected to the second doped layer 240 through the opening of the third insulating layer 250. The second electrode 260 is also electrically connected to the driving backplane 100. A material of the third insulating layer 250 may be an insulating material such as silicon dioxide, and its thickness may be set in the range of 100 nm to 500 nm, specifically it may be set to 300 nm, which is not limited here.

In some embodiments, the Micro LED structure 200 may further include a superlattice layer between the N-type semiconductor layer and the multi-quantum well layer to improve the quality of an epitaxial layer. The superlattice layer may be a periodically cross-arranged InGaN layer and a GaN layer, and the total thickness of the superlattice layer may be set in the range of 10 nm to 200 nm, specifically it may be set to 70 nm. The superlattice layer may also be of other structures, which are not limited here.

In the embodiments shown in FIG. 6 and FIG. 7, the first doped layer 220, the multi-quantum well layer 230 and the second doped layer 240 constitute an epitaxial structure. The epitaxial structure can be made on a separate substrate through processes such as deposition and etching, and then transferred to the driving backplane 100, and electrically connected to the driving backplane 100 through the first electrode 210. Then, an insulating material layer 25 is deposited as a full-face layer on a side of the epitaxial structure facing away from the driving backplane 100 by a deposition process such as chemical vapor deposition, and the third insulating layer 250 of each Micro LED structure 200 is located in the insulating material layer 25. After the insulating material layer 25 is formed, an opening is made in the third insulating layer 250 of each Micro LED structure 200 to expose the second doped layer 240, so as to facilitate subsequent connection with the second electrode 260. After the opening is made in the third insulating layer 250, a second electrode material layer 26 that fully covers a side of the insulating material layer 25 facing away from the driving backplane 100 is formed through a deposition process such as sputtering deposition, so that the second electrode material layer 26 is electrically connected to the second doped layer 240 through the opening of the insulating material layer 25, and is electrically connected to the driving backplane 100. The second electrode 260 of each of Micro LED structures 200 is located in the second electrode material layer 26, and the second electrode 260 of each of the Micro LED structures 200 covers the surface of the third insulating layer 250 of the Micro LED structure 200, and the second electrodes 260 of the Micro LED structures 200 are connected to each other to form a common electrode structure.

Since the epitaxial structure is manufactured through an etching process, due to the influence of etching deviation, a width of the epitaxial structure gradually decreases in a direction from the first doped layer 220 to the second doped layer 240, as shown in FIGS. 6 and 7, so that a cross-sectional shape of the epitaxial structure forms an approximately trapezoidal structure, and an angle between the waist of the trapezoid (in the cross-section shown in FIG. 6 and FIG. 7, shapes of the upper and lower surfaces of the epitaxial structure in the cross-section are straight lines, and a line L between endpoints on the same side of the straight lines formed by the upper and lower surfaces is the waist of the trapezoid) and the lower base of the trapezoid (in the cross-section shown in FIG. 6 and FIG. 7, the straight line formed by the lower surface of the epitaxial structure in the cross-section) ranges from 30° and 75°, specifically it may be 63°, which is not limited here.

In some embodiments, as shown in FIG. 6, an orthographic projection of the color conversion structure 300 on the driving backplane 100 is located within an orthographic projection of the first portion 510 of the first insulating layer 500 on the driving backplane 100, and the color conversion structure 300 is only disposed on a surface of the first portion 510 of the first insulating layer 500.

The Micro LED display substrate further includes: a light blocking layer 700 located at the side of the first insulating layer 500 facing away from the driving backplane 100, and filled in a gap between two adjacent Micro LED structures 200 (in the pit H formed by the first insulating layer 500) and a gap between two adjacent color conversion structures 300 to prevent color mixing. A surface of a side of the light blocking layer 700 facing away from the driving backplane 100 is connected to a surface of a side of an adjacent color conversion structure 300 facing away from the driving backplane 100 to form a continuous surface. The microlenses 400 are located at a side of the color conversion structures 300 and the light blocking layer 700 facing away from the driving backplane 100, and partially overlap with the light blocking layer 700. The light blocking layer 700 may be made of the material used to make the black matrix (referred to as BM) in the related art, or made of other light blocking materials, which is not limited here.

In the embodiment shown in FIG. 6, a spacing between the microlenses 400 (the minimum distance between the orthographic projections of the microlenses 400 on the driving backplane 100) may be set in the range of 0.1 μm to 5 μm. Specifically, it may be set to 0.5 μm. A width (diameter) of the orthographic projection of each microlens 400 on the driving backplane 100 may be set in the range of 1 μm to 5 μm. Specifically, it may be set to 3.5 μm. A height of each microlens 400 (a distance h2 from the top of the microlens 400 to the surface of the side of the color conversion structure 300 facing away from the driving backplane 100) may be set in the range of 1 μm to 5 μm. Specifically, it may be set to 2.8 μm. An orthographic projection of the first doped layer 220 of the Micro LED structure 200 on the driving backplane 100 is located within an orthographic projection of the corresponding one of the microlenses 400 on the driving backplane 100, and a width (diameter) of the orthographic projection of the first doped layer 220 on the driving backplane 100 can be set in the ranged of 1 μm to 5 μm, specifically, it may be set to 2.5 μm, which is not limited here. An orthographic projection of the second doped layer 240 of the Micro LED structure 200 on the driving backplane 100 is located within the orthographic projection of the corresponding one of the microlenses 400 on the driving backplane 100, and a width (diameter) of the orthographic projection of the second doped layer 240 on the driving backplane 100 may be set in the range of 1 μm to 5 μm, specifically it may be set to 1.2 μm. The total height of the epitaxial structure composed of the first doped layer 220, the multi-quantum well layer 230 and the second doped layer 240 of the Micro LED structure 200 may be set in the range of 1 μm to 5 μm, specifically it may be set to 3.6 μm. In a specific implementation, a distance between an edge of the orthographic projection of the microlens 400 on the driving backplane 100 and an edge of the orthographic projection of the first doped layer 220 of the Micro LED structure 200 on the driving backplane 100 may be set in the range of 0.1 5 μm, specifically it may be set to 0.6 μm. A distance between the edge of the orthographic projection of the microlens 400 on the driving backplane 100 and an edge of the orthographic projection of the second doped layer 240 of the Micro LED structure 200 on the driving backplane 100 may be set in the range of 1 μm to 5 μm, specifically, it may be set to 1.4μm.

In the embodiment shown in FIG. 6, the color conversion structure 300 may include a color conversion layer 310 and a filter layer 320. An orthographic projection of the color conversion layer 310 on the driving backplane 100 and an orthographic projection of the filter layer 320 on the driving backplane 100 are both located within the orthographic projection of the microlens 400 on the driving backplane 100. The orthographic projection of the second doped layer 240 of the Micro LED structure 200 on the driving backplane 100 is located within the orthographic projection of the color conversion layer 310 on the driving backplane 100, and the orthographic projection of the second doped layer 240 of the Micro LED structure 200 on the driving backplane 100 is located within the orthographic projection of the filter layer 320 on the driving backplane 100, so that more light emitted by the Micro LED structure 200 can be incident into the color conversion structure 300, thereby improving the light utilization rate. In a specific implementation, the orthographic projection of the color conversion layer 310 on the driving backplane 100 and the orthographic projection of the filter layer 320 on the driving backplane 100 can be set to completely overlap, which is not limited here. A width (diameter) of the orthographic projection of the color conversion layer 310 on the driving backplane 100 may be set in the range of 1 μm to 5 μm, specifically it may be set to 2 μm, and a width (diameter) of the orthographic projection of the filter layer 320 on the driving backplane 100 may be set in the range of 1 μm to 5 μm, specifically it may be set to 2 μm, which is not limited here.

In the embodiment shown in FIG. 6, the color conversion structure 300 may include only the color conversion layer 310, which is not limited herein.

In some embodiments, as shown in FIG. 7, the color conversion structure 300 completely covers the first portion 510 of the first insulating layer 500 and at least partially covers the second portion 520 of the first insulating layer 500, thereby increasing the planar size of the color conversion structure 300, increasing the pixel aperture ratio, and further increasing the amount of light emitted from the Micro LED structure 200 and incident into the corresponding color conversion structure 300, thereby improving the light utilization rate. In a specific implementation, after the color conversion structures 300 are formed at the side of the first insulating layer 500 facing away from the Micro LED structure 200, the microlenses 400 may be directly manufactured, so that each of the microlenses 400 covers the surface of the corresponding one of the color conversion structures 300, and covers at least a portion of the surface of the first insulating layer 500 that is not covered by the corresponding one of the color conversion structures 300, so that the color conversion structure 300 is wrapped in the microlens 400, and all the light emitted by the color conversion structure 300 is incident into the microlens 400, thereby improving the light utilization rate.

In a specific manufacturing process, after the color conversion structures 300 are formed on a side of the first insulating layer 500 facing away from the Micro LED structure 200, a full-coverage microlens material layer may be directly formed on a side of the color conversion structures 300 facing away from the driving backplane 100 through processes such as chemical vapor deposition, and then a plurality of microlenses 40 arranged at intervals are formed by etching the microlens material layer. After the microlenses 400 are formed, a light blocking material can be filled in a gap between adjacent microlenses 400 to form a light blocking layer 700 to prevent color mixing. In a specific implementation, along the direction perpendicular to the driving backplane 100, a height of the light blocking layer 700 is greater than or equal to a height of the color conversion structure 300, so as to better avoid color mixing. Since the color conversion structure 300 is wrapped in the microlens 400, the light emitted from a lateral surface of the color conversion structure 300 is reflected at an interface where a side wall of the microlens 400 contacts the light blocking layer 700, and the propagation direction of the light is adjusted and then emitted to the top of the microlens 400, thereby improving the light output direction and enhancing the light output efficiency.

In the embodiment shown in FIG. 7, a spacing between the microlenses 400 (the minimum distance between orthographic projections of the microlenses 400 on the driving backplane 100) may be set in the range of 0.1 μm to 5 μm. Specifically, it may be set to 0.3 μm. A width (diameter) of the orthographic projection of each microlens 400 on the driving backplane may be set in the range of 1 μm to 5 μm. Specifically, it may be set to 3.5 μm. A distance h2 from a top of the microlens 400 to a surface of a side of the color conversion structure 300 facing away from the driving backplane 100 may be set in the range of 1 μm to 5 μm. Specifically, it may be set to 2.8 μm. An orthographic projection of the first doped layer 220 of the Micro LED structure 200 on the driving backplane 100 is located within the orthographic projection of the corresponding one of the microlenses 400 on the driving backplane 100, and a width (diameter) of the orthographic projection of the first doped layer 220 on the driving backplane 100 may be set in the range of 1 μm to 5 μm, specifically, it may be set to 2.5 μm. An orthographic projection of the second doped layer 240 of the Micro LED structure 200 on the driving backplane 100 is located within the orthographic projection of the corresponding one of the microlenses 400 on the driving backplane 100, and a width (diameter) of the orthographic projection of the second doped layer 240 on the driving backplane 100 may be set in the range of 1 μm to 5 μm, and specifically, it may be set to 1.2 μm. The total height of the epitaxial structure composed of the first doped layer 220, the multi-quantum well layer 230 and the second doped layer 240 of the Micro LED structure 200 may be set in the range of 1 μm to 5 μm, specifically 3.6 μm. In a specific implementation, a distance between an edge of the orthographic projection of the microlens 400 on the driving backplane 100 and an edge of the orthographic projection of the first doped layer 220 of the Micro LED structure 200 on the driving backplane 100 may be set to 0.1 μm to 5 μm, specifically it may be set to 0.6 μm. A distance between the edge of the orthographic projection of the microlens 400 on the driving backplane 100 and an edge of the orthographic projection of the second doped layer 240 of the Micro LED structure 200 on the driving backplane 100 may be set to 1 μm to 5 μm, specifically, it may be set to 1.4 μm.

The film layers not mentioned in the embodiment shown in FIG. 7 may be arranged with reference to the corresponding film layers in FIG. 6, and will not be described in detail here.

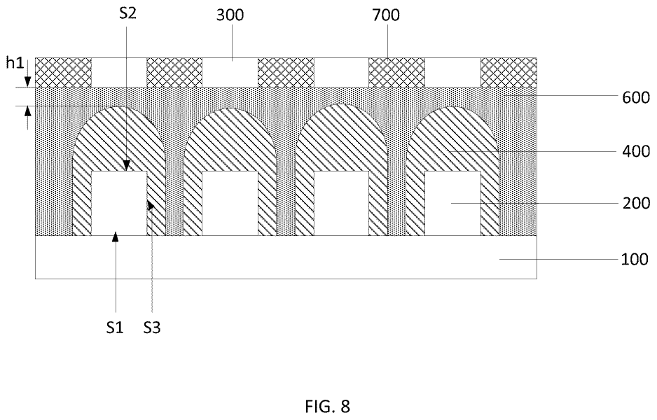

FIG. 8 is an eighth schematic structural diagram of a cross-section of a Micro LED display substrate provided by an embodiment of the disclosure.

In some embodiments, as shown in FIG. 8, the color conversion structure 300 is located at a side of the microlenses 400 facing away from the Micro LED structures 200.

The Micro LED structure 200 includes a bottom surface S1 and a top surface S2 that are arranged opposite to each other, and a side surface S3 that is located between the bottom surface S1 and the top surface S2 and connected to the bottom surface S1 and the top surface S2 respectively. The microlens 400 covers the top surface S2 and at least a portion of the side surface S3 of the Micro LED structure 200, so as to at least partially wrap the Micro LED structure 200 within the microlens 400. In a specific implementation, the light emitted by the Micro LED structure 200 exhibits a Lambertian distribution, and part of the light emitted by the Micro LED structure 200 propagates in a direction perpendicular to the driving backplane 100, and part of the light propagates to both sides of the Micro LED structure 200. Since the Micro LED structure 200 is at least partially wrapped within the microlens 400, the light emitted from the both sides the Micro LED structure 200 can be reflected by the side wall of the microlens 400, thereby improving the light emission direction, so that more light propagates in a direction perpendicular to the driving backplane 100, and improving the utilization rate of light. Furthermore, the microlenses 400 are usually made of insulating material. By wrapping the Micro LED structure 200 with the microlens 400, the use of an insulating layer can be reduced, which is beneficial to reducing the thickness of the Micro LED display substrate and reducing the production cost.

In some embodiments, as shown in FIG. 8, the Micro LED display substrate further includes: a second insulating layer 600. The second insulating layer 600 is located at a side of the microlenses 400 facing away from the driving backplane 100, and is located between the color conversion structures 300 and the microlenses 400. The second insulating layer 600 covers the surfaces of the microlenses 400 and fills gaps between the microlenses 400 to form a flat surface at the side of the microlenses 400 facing away from the driving substrate 100, thereby playing a role of planarization and protection, so as to facilitate the subsequent manufacture of the color conversion structures 300. In a specific implementation, a material of the second insulating layer 600 may be an organic material, such as polyimide, acrylic, photoresist, etc., which is not limited here. A height of the second insulating layer 600 is greater than a height of the microlens 400. In a specific implementation, a distance h1 between a surface of the second insulating layer 600 facing away from the driving backplane 100 and the highest point of the top of the microlens 400 ranges from 0.1 μm to 2 μm, and specifically it may be set to 0.8 μm, which is not limited here.

In some embodiments, as shown in FIG. 8, the Micro LED display substrate further includes a light blocking layer 700. The light blocking layer 700 is located in the gap between adjacent color conversion structures 300 to prevent color mixing. In a specific implementation, the orthographic projection of the color conversion structure 300 on the driving backplane 100 is located within the orthographic projection of the microlens 400 on the driving backplane 100, and an orthographic projection of the light blocking layer 700 on the driving backplane 100 covers the gap between the orthographic projections of adjacent microlenses 400 on the driving backplane 100.

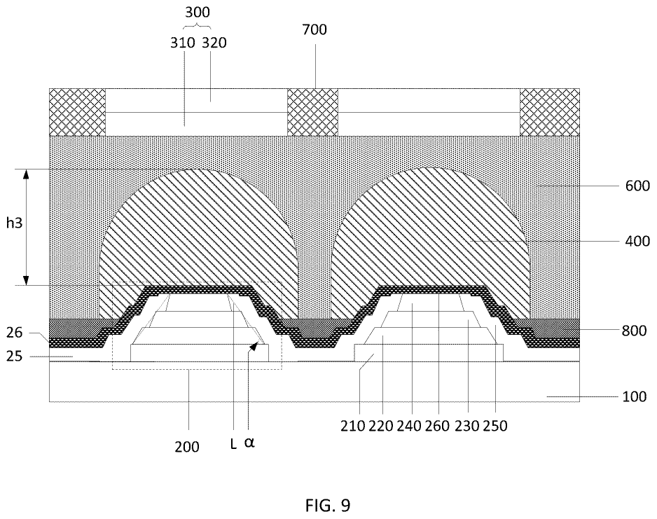

FIG. 9 is a ninth schematic structural diagram of a cross-section of a Micro LED display substrate provided by an embodiment of the disclosure.

In the embodiment shown in FIG. 8, the Micro LED structure 200 may be a horizontal structure or a vertical structure. The P electrode and the N electrode of the Micro LED structure 200 with a horizontal structure are located at the same side of the Micro LED structure 200, and the P electrode and the N electrode of the Micro LED structure 200 with a vertical structure are located on opposite sides of the Micro LED structure 200. FIG. 9 illustrates a specific structure of the Micro LED display substrate in the embodiment shown in FIG. 8 by taking a Micro LED structure 200 with a vertical structure as an example. As shown in FIG. 9, the Micro LED structure 200 includes a first electrode 210, a first doped layer 220, a multi-quantum well layer (MQW) 230, a second doped layer 240, a third insulating layer 250, and a second electrode 260 stacked in a direction away from the driving backplane 100. In a specific implementation, the specific structure of the Micro LED structure 200 is the same as the embodiment shown in FIG. 6 and FIG. 7, and may be arranged with reference to FIG. 6 and FIG. 7, which will not be described in detail here.

In the embodiment shown in FIG. 9, the spacing between the microlenses 400 (the minimum distance between the orthographic projections of the microlenses 400 on the driving backplane 100) may be set in the range of 0.1 μm to 5 μm. Specifically, it may be set to 0.3 μm. The width (diameter) of the orthographic projection of each of the microlenses 400 on the driving backplane 100 may be set in the range of 1 μm to 5 μm. Specifically, it may be set to 3.5 μm. The distance h3 from a top of the microlens 400 to a surface of a side of the second electrode 260 on the side away from the driving backplane 100 may be set in the range of 1 μm to 5 μm. Specifically, it may be set to 2.8 μm. The orthographic projection of the first doped layer 220 of the Micro LED structure 200 on the driving backplane 100 is located within the orthographic projection of the corresponding one of the microlenses 400 on the driving backplane 100, and the width (diameter) of the orthographic projection of the first doped layer 220 on the driving backplane 100 may be set in the range of 1 μm to 5 μm. Specifically, it may be set to 2.5 μm. The orthographic projection of the second doped layer 240 of the Micro LED structure 200 on the driving backplane 100 is located within the orthographic projection of the corresponding one of the microlenses 400 on the driving backplane 100, and the width (diameter) of the orthographic projection of the second doped layer 240 on the driving backplane 100 may be set in the range of 1 μm to 5 μm. Specifically, it may be set to 1.2 μm. The total height of the epitaxial structure composed of the first doped layer 220, the multi-quantum well layer 230 and the second doped layer 240 of the Micro LED structure 200 may be set in the range of 1 μm to 5 μm, specifically, it may be set to 3.6 μm. In a specific implementation, the distance between the edge of the orthographic projection of the microlens 400 on the driving backplane 100 and the edge of the orthographic projection of the first doped layer 220 of the Micro LED structure 200 on the driving backplane 100 can be set in the range of 0.1 μm to 5 μm, specifically, it may be set to 0.6 μm. The distance between the edge of the orthographic projection of the microlens 400 on the driving backplane 100 and the edge of the orthographic projection of the second doped layer 240 of the Micro LED structure 200 on the driving backplane 100 may be set in the range of 1 μm to 5 μm, specifically, it may be set to 1.4 μm.

In the embodiment shown in FIG. 9, the color conversion structure 300 may include a color conversion layer 310 and a filter layer 320. An orthographic projection of the color conversion layer 310 on the driving backplane 100 and an orthographic projection of the filter layer 320 on the driving backplane 100 are both located within the orthographic projection of the microlens 400 on the driving backplane 100. The orthographic projection of the Micro LED structure 200 on the driving backplane 100 is located within the orthographic projection of the color conversion layer 310 on the driving backplane 100, and the orthographic projection of the Micro LED structure 200 on the driving backplane 100 is located within the orthographic projection of the filter layer 320 on the driving backplane 100, so that more light emitted by the Micro LED structure 200 can be incident into the color conversion structure 300, thereby improving the light utilization rate. In a specific implementation, the orthographic projection of the color conversion layer 310 on the driving backplane 100 may completely overlap with the orthographic projection of the filter layer 320 on the driving backplane 100, which is not limited here. A width (diameter) of the orthographic projection of the color conversion layer 310 on the driving backplane 100 may be set in the range of 1 μm to 5 μm, and specifically, it may be set to 3 μm. A width (diameter) of the orthographic projection of the filter layer 320 on the driving backplane 100 may be set in the range of 1 μm to 5 μm, and specifically, it may be set to 3 μm, which is not limited here. A width of the light blocking layer 700 is adapted to the width of the gap between adjacent color conversion structures 300, and its range may be 0.5 μm to 2 μm, which is not limited here.

The film layers not mentioned in the embodiment shown in FIG. 9 may be arranged with reference to the corresponding film layers in FIG. 6, and will not be described in detail here.

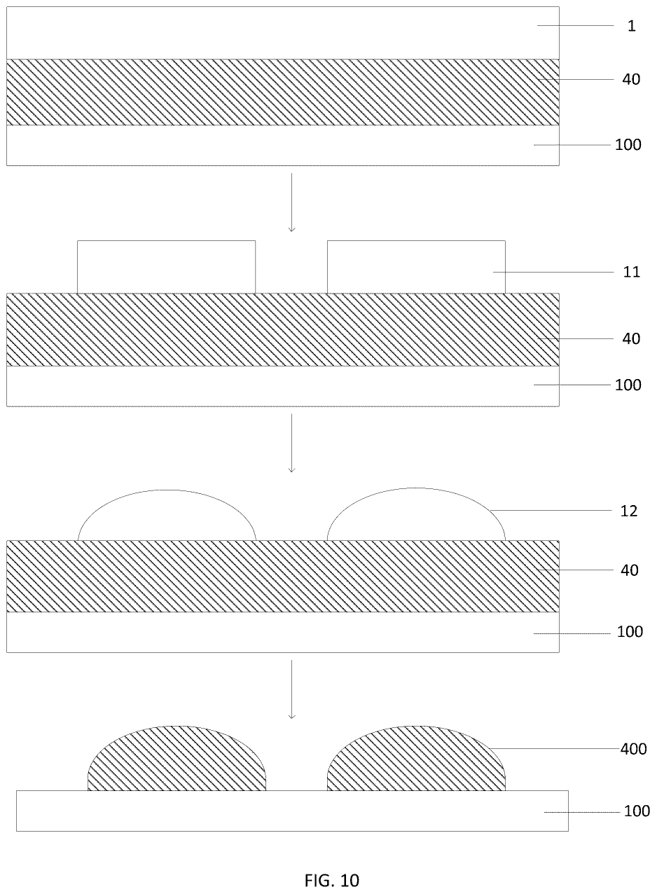

FIG. 10 is a schematic diagram of a process for manufacturing a microlens according to an embodiment of the disclosure.

In some embodiments, as shown in FIG. 4-FIG. 9, a side of the microlens 400 facing away from the driving substrate 100 may be set as a curved surface. In a specific implementation, the curved surface may be a spherical surface. As shown in FIG. 10, forming spherical microlenses 400 may include following steps: First, a microlens material layer 40 is deposited on the driving backplane 100 that has completed the previous process (the Micro LED structures 200 have been formed or the color conversion structures 300 have been formed), and a photoresist layer 1 is covered on a side of the microlens material layer 40 facing away from the driving backplane 100. Then, the photoresist layer 1 is etched to form a plurality of etched patterns 11 corresponding to the microlenses 400 one by one, and an orthographic projection of the etched pattern 11 on the driving backplane 100 covers an orthographic projection of the Micro LED structure 200 on the driving backplane 100, and a distance between an edge of the orthographic projection of the etched pattern 11 on the driving backplane 100 and an edge of the orthographic projection of the Micro LED structure 200 on the driving backplane 100 ranges from 1 μm to 10 μm, to reserve sufficient etching margin. After the etched patterns 11 are formed, the etched patterns 11 are heated by a thermal reflow process so that the etched patterns 11 soften and deform at high temperature to form a plurality of spherical patterns 12. The heating temperature needs to be higher than the glass softening temperature of the etched patterns 11, typically ranging from 100 °C to 110 °C or 110 °C to 120 °C, which is not limited here. After the spherical patterns 12 are formed, the spherical patterns 12 and the microlens material layer 40 are etched simultaneously by a dry etching process. During the etching process, regions of the microlens material layer 40 that are not covered by the spherical patterns 12 are preferentially etched compared to regions of the microlens material layer 40 that are covered by the spherical patterns 12. As the etching proceeds, the spherical patterns 12 undergo ashing during the etching process, and the thinner regions of the spherical patterns 12 preferentially exposes the microlens material layer 40 blocked by it, and the exposed portion of the microlens material layer 40 is then etched. Finally, the spherical patterns 12 are completely ashed and thus removed from the surface of the microlens material layer 40, and a plurality of spherical surfaces corresponding to the spherical patterns 12 are formed on the microlens material layer 40. The microlens material layer 40 is further etched to obtain a plurality of spherical microlenses 400 arranged at intervals. In a specific implementation, the surface of the microlens 400 may also be a curved surface of other shapes, which is not limited here.

In some embodiments, a side of the microlens 400 facing away from the driving substrate 100 may be set to a plane. The plane microlens 400 does not need to be subjected to a thermal reflow process during production. After the etched patterns 11 are formed, the microlens material layer 40 may be etched by a dry etching process, which will not be described in detail here.

In some embodiments, as shown in FIGS. 6, 7 and 9, the Micro LED display substrate further includes a conductive filling layer 800. The conductive filling layer 800 is located in a gap between two adjacent Micro LED structures 200. In a specific implementation, the conductive filling layer 800 is directly formed on the surface of the second electrode 260 and is electrically connected with the second electrode 260. The conductive filling layer 800 may be used as an auxiliary electrode to increase an area of a cross-section of the common electrode structure formed by interconnecting the second electrodes 260 of the Micro LED structures 200, thereby reducing a surface resistance. In addition, since a thickness of the second electrode material layer 26 where the second electrodes 260 are located is relatively thin, it is easy to break at the corners and step positions of the film layer. By connecting the second electrodes 260 of two adjacent Micro LED structures 200 through the conductive filling layer 800, the risk of breaking the common electrode structure can be reduced. In the embodiments shown in FIGS. 6 and 7, after forming the second electrode material layer 26 where the second electrodes 260 are located, a conductive filling layer 800 may be deposited in the gap between two adjacent Micro LED structures 200, so that the conductive filling layer 800 is directly formed on the surface of the second electrode 260, and then the first insulating layer 500 is formed at the side of the second electrode 260 and the conductive filling layer 800 facing away from the driving substrate 100. In the embodiment shown in FIG. 9, after forming the second electrode material layer 26 where the second electrodes 260 are located, a conductive filling layer 800 may be deposited in the gap between two adjacent Micro LED structures 200, so that the conductive filling layer 800 is directly formed on the surface of the second electrode 260, and then the microlens 400 is formed at the side of the second electrode 260 and the conductive filling layer 800 facing away from the driving substrate 100. This is not limited here.

In a specific implementation, in a direction perpendicular to the driving backplane 100, the height of the conductive filling layer 800 is less than the height of the Micro LED structure 200 to avoid increasing costs due to excessive filling of conductive materials.

In a second aspect of the embodiments of the disclosure, a display apparatus is provided, including the Micro LED display substrate provided by any of the above embodiments. In some embodiments, the display apparatus may be a VR/AR display apparatus, and the resolution of the VR/AR display apparatus may be improved, thereby achieving full-color display. The display apparatus may also be other display devices such as a mobile phone, a tablet, a laptop computer, a monitor, etc., which are not limited here. The display apparatus provided by the disclosure has the same technical effect as the Micro LED display substrate provided by any of the above embodiments, which will not be described in detail here.

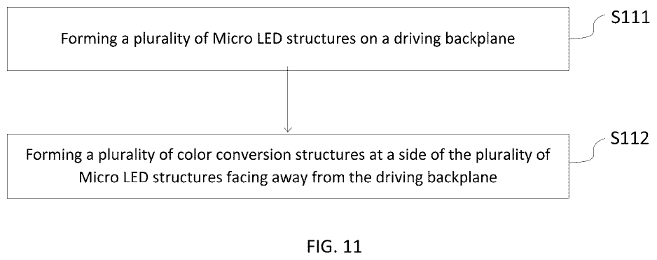

FIG. 11 is a flow chart of a method for manufacturing a Micro LED display substrate provided by an embodiment of the disclosure.

A third aspect of the embodiments of the disclosure provides a method for manufacturing a Micro LED display substrate. As shown in FIG. 11, the method for manufacturing a Micro LED display substrate provided by the embodiments of the disclosure includes the following steps.
S111: forming a plurality of Micro LED structures on a driving backplane.
S112: forming a plurality of color conversion structures at a side of the plurality of Micro LED structures facing away from the driving backplane.

In the method for manufacturing the Micro LED display substrate provided by the embodiments of the disclosure, the plurality of Micro LED structures are first formed on the driving backplane, and then the plurality of color conversion structures are formed at the side of the plurality of Micro LED structures facing away from the driving backplane. The plurality of Micro LED structures are used to emit light of the same color. As shown in FIG. 1, one color conversion structure 300 corresponds to one Micro LED structure 200, and each of the color conversion structures 300 is located at a side of a corresponding one of the Micro LED structures facing away from the driving backplane. The color conversion structure 300 converts the light emitted by the corresponding one of the Micro LED structures 200 into light of a set color, and the color conversion structures 300 may emit light of different colors, thereby realizing the display of full-color images.

In some embodiments, after the forming the plurality of color conversion structures at the side of the plurality of Micro LED structures 200 away from the driving backplane 100, a plurality of microlenses 400 arranged at intervals may be formed at a side of the color conversion structures 300 facing away from the driving backplane 100. As shown in FIG. 5, one microlens 400 corresponds to one Micro LED structure 200, and each of the microlenses 400 is located at a side of a corresponding one of the Micro LED structures 200 facing away from the driving backplane 100. An orthographic projection of the color conversion structures 300 on the driving backplane 100 is located within an orthographic projection of the microlenses 400 on the driving backplane 100, thereby ensuring that more light emitted from the color conversion structure 300 is incident into the microlens 400, and the light-emitting angle is adjusted by the microlens 400 to improve the light utilization rate.

In a specific implementation, before the forming the plurality of color conversion structures 300 at the side of the Micro LED structure 200 facing away from the driving backplane 100, as shown in FIG. 5, a first insulating layer 500 may also be deposited at the side of the plurality of Micro LED structures 200 facing away from the driving backplane 100. The Micro LED structure 200 includes a bottom surface S1 and a top surface S2 that are arranged opposite to each other, and a side surface S3 that is located between the bottom surface S1 and the top surface S2 and is connected to the bottom surface S1 and the top surface S2 respectively. The first insulating layer 500 includes a first portion 510 that covers the top surface S2 of the Micro LED structure 200, and a second portion 520 that is connected to the first portion 510 and covers the side surface S3 of the Micro LED structure 200. The first insulating layer 500 can play an insulating and protective role on the Micro LED structure 200, so as to facilitate the manufacture of the color conversion structure 300.

In some embodiments, as shown in FIG. 6, when the plurality of color conversion structures 300 are formed at the side of the Micro LED structure 200 facing away from the driving backplane 100, the orthographic projection of the color conversion structure 300 on the driving backplane 100 may be located within an orthographic projection of the first portion 510 of the first insulating layer 500 on the driving backplane 100. After forming the plurality of color conversion structures 300 and before forming the microlenses 400, a light blocking layer 700 may be formed at a side of the first insulating layer 500 facing away from the driving backplane 100. The light blocking layer 700 is filled in a gap between two adjacent Micro LED structures 200 and a gap between two adjacent color conversion structures 300. A surface of a side of the light blocking layer 700 facing away from the driving backplane 100 is connected to a surface of a side of the adjacent color conversion structure 300 facing away from the driving backplane 100 to form a continuous surface. Then, the microlenses 400 are formed at a side of the color conversion structure 300 and the light blocking layer 700 facing away from the driving backplane 100, so that the microlens 400 covers the color conversion structure 300 and a portion of the light blocking layer 700.

In some embodiments, as shown in FIG. 7, when the plurality of color conversion structures 300 are formed at the side of the Micro LED structures 200 facing away from the driving backplane 100, the color conversion structure 300 may completely cover the first portion 510 of the first insulating layer 500 and at least partially cover the second portion 520 of the first insulating layer 500. After the color conversion structures 300 are manufactured, a plurality of microlenses 400 arranged at intervals are manufactured at the side of the color conversion structures 300 facing away from the driving backplane 100, and the microlenses 400 cover the surface of the color conversion structure 300 and at least cover a portion of the surface of the first insulating layer 500 not covered by the color conversion structure 300, so that the color conversion structure 300 is wrapped in the microlenses 400. After the microlenses 400 are formed, a light blocking layer 700 is formed in a gap between two adjacent microlenses 400. In a direction perpendicular to the driving backplane 100, a height of the light blocking layer 700 is greater than or equal to a height of the color conversion structure 300.

In some embodiments, as shown in FIG. 8 and FIG. 9, the Micro LED structure 200 includes a bottom surface S1 and a top surface S2 that are oppositely disposed, and a side surface S3 that is located between the bottom surface S1 and the top surface S2 and connected to the bottom surface S1 and the top surface S2 respectively. In a specific implementation, before forming the plurality of color conversion structures 300 at the side of the Micro LED structures 200 facing away from the driving backplane 100, a plurality of microlenses 400 arranged at intervals may be formed at the side of the Micro LED structures 200 facing away from the driving backplane 100. Here, one microlens 400 corresponds to one Micro LED structure 200, and each of the microlenses 400 is located at a side of the corresponding one of the Micro LED structures 200 facing away from the driving backplane 100. An orthographic projection of the color conversion structures 300 on the driving backplane 100 and an orthographic projection of the Micro LED structures 200 on the driving backplane are both located within an orthographic projection of the microlenses 400 on the driving backplane 100. The microlens 400 covers the top surface S2 and at least a portion of the side surface S3 of the Micro LED structure, so as to at least partially enclose the Micro LED structure 200 within the microlens 400, thereby improving light utilization.

In a specific implementation, the specific manufacturing method of the Micro LED display substrate provided by the embodiments of the disclosure may refer to the specific structure of the aforementioned Micro LED display substrate, which will not be described in detail here.

While preferred embodiments of the disclosure have been described, additional changes and modifications to these embodiments can be made by those skilled in the art once the basic inventive concept is appreciated. Therefore, it is intended that the appended claims be construed to cover the preferred embodiment as well as all changes and modifications which fall within the scope of the disclosure.

Apparently, those skilled in the art can make various changes and modifications to the embodiments of the disclosure without departing from the spirit and scope of the embodiments of the disclosure. In this way, if the modifications and variations of the embodiments of the disclosure fall within the scope of the claims of the disclosure and equivalent technologies, the disclosure also intends to include these modifications and variations.

1. A Micro light-emitting diode (LED) display substrate, comprising:
a driving backplane;
a plurality of Micro LED structures, arranged on the driving backplane at intervals and electrically connected to the driving backplane; wherein the plurality of Micro LED structures are configured to emit light of a same color; and
a plurality of color conversion structures, wherein one color conversion structure corresponds to one Micro LED structure, each of the plurality of color conversion structures is located at a side of a corresponding one of the plurality of Micro LED structures facing away from the driving backplane, and is configured to convert light emitted by the corresponding one of the plurality of Micro LED structures into light of a set color.

2. The Micro LED display substrate according to claim 1, further comprising:
a plurality of microlenses arranged at intervals;
wherein one microlens corresponds to one Micro LED structure, and each of the plurality of microlenses is located at a side of a corresponding one of the plurality of Micro LED structures facing away from the driving backplane.

3. The Micro LED display substrate according to claim 2, wherein the plurality of color conversion structures are located between the plurality of microlenses and the plurality of Micro LED structures; an orthographic projection of the plurality of color conversion structures on the driving backplane is located within an orthographic projection of the plurality of microlenses on the driving backplane;
the Micro LED display substrate further comprises:
a first insulating layer, located between the plurality of Micro LED structures and the plurality of color conversion structures, and covering the plurality of Micro LED structures;
wherein the Micro LED structure comprises:
a bottom surface and a top surface arranged opposite to each other; and
a side surface, located between the bottom surface and the top surface and connected to the bottom surface and the top surface respectively;
wherein the first insulating layer comprises a first portion covering the top surface of the Micro LED structure, and a second portion connected to the first portion and covering the side surface of the Micro LED structure.

4. The Micro LED display substrate according to claim 3, wherein,
the orthographic projection of the color conversion structure on the driving backplane is located within an orthographic projection of the first portion of the first insulating layer on the driving backplane;
the Micro LED display substrate further comprises:
a light blocking layer, located at a side of the first insulating layer facing away from the driving backplane and being filled in a gap between two adjacent Micro LED structures and a gap between two adjacent color conversion structures;
wherein a surface of a side of the light blocking layer facing away from the driving backplane is connected to a surface of a side of an adjacent color conversion structure facing away from the driving backplane to form a continuous surface; the microlens is located at a side of the color conversion structure and the light blocking layer facing away from the driving backplane and partially overlap with the light blocking layer.

5. The Micro LED display substrate according to claim 3, wherein,
the color conversion structure completely covers the first portion of the first insulating layer and at least partially covers the second portion of the first insulating layer;
the microlens covers a surface of the color conversion structure and covers at least a portion of a surface of the first insulating layer not covered by the color conversion structure, to wrap the color conversion structure within the microlens;
the Micro LED display substrate further comprises:
a light blocking layer, filled in a gap between two adjacent microlenses;
wherein in a direction perpendicular to the driving backplane, a height of the light blocking layer is greater than or equal to a height of the color conversion structure.

6. The Micro LED display substrate according to claim 2, wherein the plurality of color conversion structures are located at a side of the plurality of microlenses facing away from the plurality of Micro LED structures;
the Micro LED structure comprises:
a bottom surface and a top surface arranged opposite to each other; and
a side surface, located between the bottom surface and the top surface and connected to the bottom surface and the top surface respectively;
wherein the microlens covers the top surface and at least a portion of the side surface of the Micro LED structure, to at least partially wrap the Micro LED structure within the microlens.

7. The Micro LED display substrate according to claim 2, wherein surfaces of the plurality of microlenses facing away from the driving backplane are flat surfaces or curved surfaces.

8. The Micro LED display substrate according to claim 2, further comprising:
a second insulating layer, located at a side of the plurality of microlenses facing away from the driving backplane; wherein the second insulating layer is in direct contact with the plurality of microlenses and covers the plurality of microlenses and gaps between the plurality of microlenses, to form a flat surface at the side of the plurality of microlenses facing away from the driving backplane.

9. The Micro LED display substrate according to claim 1, wherein the Micro LED structure comprises:
a first electrode, located at a side facing the driving backplane and electrically connected to the driving backplane;
a first doped layer, located at a side of the first electrode facing away from the driving backplane;
a multi-quantum well layer, located at a side of the first doped layer facing away from the first electrode;
a second doped layer, located at a side of the multi-quantum well layer facing away from the first doped layer;
a third insulating layer, located at a side of the second doped layer facing away from the driving backplane; wherein the third insulating layer comprises an opening exposing the second doped layer; the third insulating layer covers surfaces of the multi-quantum well layer, the first doped layer and the first electrode, to wrap the multi-quantum well layer, the first doped layer and the first electrode within the third insulating layer;
a second electrode, located at a side of the third insulating layer facing away from the driving backplane; wherein the second electrode covers a surface of the third insulating layer and is electrically connected to the second doped layer through the opening; and the second electrode is further electrically connected to the driving backplane;
the Micro LED display substrate further comprises:
a conductive filling layer, located in a gap between two adjacent Micro LED structures; wherein the conductive filling layer is directly formed at a surface of the second electrode and is electrically connected to the second electrode.

10. The Micro LED display substrate according to claim 9, wherein, in a direction perpendicular to the driving backplane, a height of the conductive filling layer is less than a height of the Micro LED structure.

11. The Micro LED display substrate according to claim 1, wherein the color conversion structure comprises a color conversion layer; the color conversion layer is configured to convert at least part of the light emitted by the corresponding one of the Micro LED structures into the light of the set color.

12. The Micro LED display substrate according to claim 11, wherein the color conversion structure further comprises:
a filter layer, located at a side of the color conversion layer facing away from the Micro LED structure;
wherein the filter layer is configured to filter out light with a color different from a color of light emitted by the color conversion layer after color conversion.

13. A display apparatus, comprising the Micro LED display substrate according to claim 1.

14. A method for manufacturing a Micro light-emitting diode (LED) display substrate, comprising:
forming a plurality of Micro LED structures on a driving backplane;
forming a plurality of color conversion structures at a side of the plurality of Micro LED structures facing away from the driving backplane; wherein one color conversion structure corresponds to one Micro LED structure, and each of the plurality of color conversion structures is located at a side of a corresponding one of the plurality of Micro LED structures facing away from the driving backplane.

15. The method according to claim 14, further comprising:
forming a plurality of microlenses arranged at intervals at a side of the plurality of color conversion structures facing away from the driving backplane; wherein one microlens corresponds to one Micro LED structure, and each of the plurality of microlenses is located at a side of a corresponding one of the Micro LED structures facing away from the driving backplane;
wherein before the forming the plurality of color conversion structures at the side of the plurality of Micro LED structures facing away from the driving backplane, the method further comprises:
depositing a first insulating layer at the side of the plurality of Micro LED structures facing away from the driving backplane;
wherein the Micro LED structure comprises a bottom surface and a top surface arranged opposite to each other, and a side surface located between the bottom surface and the top surface and connected to the bottom surface and the top surface respectively; the first insulating layer comprises a first portion covering the top surface of the Micro LED structure, and a second portion connected to the first portion and covering the side surface of the Micro LED structure.

16. The method according to claim 15, wherein an orthographic projection of the color conversion structure on the driving backplane is located within an orthographic projection of the first portion of the first insulating layer on the driving backplane;
before the forming the plurality of microlenses arranged at intervals at the side of the plurality of color conversion structures facing away from the driving backplane, the method further comprises:
forming a light blocking layer at a side of the first insulating layer facing away from the driving backplane;
wherein the light blocking layer is filled in a gap between two adjacent Micro LED structures and a gap between two adjacent color conversion structures; a surface of a side of the light blocking layer facing away from the driving backplane is connected to a surface of a side of an adjacent color conversion structure facing away from the driving backplane, to form a continuous surface;
the forming the plurality of microlenses arranged at intervals at the side of the plurality of color conversion structures facing away from the driving backplane comprises:
forming the plurality of microlenses at a side of the plurality of color conversion structures and the light blocking layer facing away from the driving backplane.

17. The method according to claim 15, wherein
the color conversion structure completely covers the first portion of the first insulating layer and at least partially covers the second portion of the first insulating layer;
the microlens covers a surface of the color conversion structure and covers at least a portion of a surface of the first insulating layer not covered by the color conversion structure, to wrap the color conversion structure within the microlens;
the method further comprises:
forming a light blocking layer in a gap between two adjacent microlenses;
wherein, in a direction perpendicular to the driving backplane, a height of the light blocking layer is greater than or equal to a height of the color conversion structure.

18. The method according to claim 14, wherein the Micro LED structure comprises a bottom surface and a top surface arranged opposite to each other, and a side surface located between the bottom surface and the top surface and connected to the bottom surface and the top surface respectively;
before the forming the plurality of color conversion structures at the side of plurality of the Micro LED structures facing away from the driving backplane, the method further comprises:
forming a plurality of microlenses arranged at intervals at the side of the plurality of Micro LED structures facing away from the driving backplane;
wherein one microlens corresponds to one Micro LED structure, and each of the plurality of microlenses is located at a side of a corresponding one of the plurality of Micro LED structures facing away from the driving backplane; an orthographic projection of the color conversion structure on the driving backplane and an orthographic projection of the Micro LED structure on the driving backplane are both located within an orthographic projection of the microlens on the driving backplane; and the microlens covers the top surface and at least a portion of the side surface of the Micro LED structure, to at least partially wrap the Micro LED structure within the microlens;
the forming the plurality of color conversion structures at the side of the plurality of Micro LED structures facing away from the driving backplane comprises:
forming the plurality of color conversion structures at the side of the plurality of microlenses facing away from the driving backplane.
